(19) United States
(12) Patent Application Publication
(10) Pub. No.: US 2026/0304966 A1
(43) Pub. Date: Oct. 1, 2026

(54) PLATE-TYPE PHOTOVOLTAIC MODULE LAMINATOR AND LAMINATING PLATE PRESSING DRIVE DEVICE THEREFOR

(71) Applicant: Wuxi Zhichuangsheng Automation Equipment Co., Ltd., Wuxi (CN)

(72) Inventors: Liang ZHANG, Wuxi (CN); Lei SHI, Wuxi (CN); Chenyang WANG, Wuxi (CN); Jiale HE, Wuxi (CN); Zhiyu WANG, Wuxi (CN); Kezeng ZHAO, Wuxi (CN); Dongdong SONG, Wuxi (CN)

(73) Assignee: Wuxi Zhichuangsheng Automation Equipment Co., Ltd., Wuxi (CN)

(21) Appl. No.: 19/629,078

(22) Filed: Mar. 26, 2026

(30) Foreign Application Priority Data
Mar. 31, 2025 (CN) 202510391442.1

(51) Int. Cl. H10F 19/80; H10F 19/40; H10F 71/00

(52) U.S. Cl. CPC H10F 19/80; H10F 19/40; H10F 71/137

(57) ABSTRACT

A laminating plate pressing drive device for the photovoltaic module laminator includes a sealed chamber housing; where a gas-sealed elastic component is provided within the sealed chamber housing; an outer periphery of the gas-sealed elastic component is fixedly connected to a side of the gas-sealed chamber housing, and divides a sealed chamber into an upper sealed chamber and a lower sealed chamber that are not communicated with each other; and a corrugated pipe is provided within the lower sealed chamber. The laminating plate pressing drive device and the plate-type photovoltaic module laminator result in more balanced pressure application by the laminating plate pressing drive device. Each drive device is controlled by the identical air source, resulting in consistent expansion and contraction of the gas-sealed elastic component. As a result, the time difference in contact with the photovoltaic module is small, the pressure application uniformity is good.

### CROSS REFERENCE TO THE RELATED APPLICATIONS

This application is based upon and claims priority to Chinese Patent Application No. 202510391442.1, filed on Mar. 31, 2025, the entire contents of which are incorporated herein by reference.

### TECHNICAL FIELD

The present invention relates to the technical field of photovoltaic module lamination equipment, and particularly to a rigid plate-type photovoltaic module laminator and a laminating plate pressing drive device therefor.

### BACKGROUND

Currently, the sizes of photovoltaic modules increase continuously. For the previously widely used silicone plate-type photovoltaic module laminators, because the silicone plate covers the edges of the module under vacuum during lamination, the periphery of the module is subjected to greater extrusion pressure than other areas. This results in a thinner periphery compared to other parts of the module, which is more pronounced in the lamination of large-size photovoltaic modules. While rigid plate-type photovoltaic module laminators theoretically provide uniform pressure on the photovoltaic module through planar pressing, they have encountered numerous problems in actual testing. For example, they cannot withstand high pressure, leading to insufficient pressure on the module and reduced production efficiency. Mechanical drive devices, such as a hydraulic cylinder used as a pressure source, provide a driving force for the laminating plate, thus enabling the laminating plate to compress photovoltaic modules. However, the mechanical drive devices themselves have a certain size and height, so that it is difficult to practically utilize them in multilayer photovoltaic module laminators. More importantly, as the sizes of photovoltaic modules increase, the surface area of the laminating plate also increases, requiring multiple mechanical drive devices to drive. However, it is complex to adjust the force output of the mechanical devices, and it is difficult for multiple mechanical drive devices to synchronize their movements, making pressure adjustment challenging. Therefore, this technology only remains at the stage of theoretical design and testing, without widespread application. To address this, our organization has conducted in-depth technical research on photovoltaic module laminators and achieved technological innovations and breakthroughs.

### SUMMARY

An objective of the present invention is to address the technical problem of uneven lamination of photovoltaic modules by the photovoltaic module laminators in the prior art, and to provide a plate-type photovoltaic module laminator and a laminating plate pressing drive device therefor.

The technical solution of the present invention to solve the technical problem is as follows:

A laminating plate pressing drive device for a photovoltaic module laminator includes a sealed chamber housing; where a gas-sealed elastic component is provided within the sealed chamber housing; an outer periphery of the gas-sealed elastic component is fixedly connected to a side of the gas-sealed chamber housing, and divides a sealed chamber into an upper sealed chamber and a lower sealed chamber that are not communicated with each other; a corrugated pipe is provided within the lower sealed chamber; one end of the corrugated pipe is hermetically and fixedly connected to the gas-sealed elastic component, and the other end of the corrugated pipe is fixedly connected to a lower end of the sealed chamber housing; a fixing shaft is located inside the corrugated pipe, where one end of the fixing shaft is fixedly connected to the gas-sealed elastic component, and the other end of the fixing shaft is configured to be fixedly connected to a laminating plate; both the upper sealed chamber and the lower sealed chamber are provided with gas channels that are communicated with a vacuum device and an inflation device.

The gas-sealed elastic component includes a flexible gas-sealed elastic component and a movable plate, the movable plate is located below the flexible gas-sealed elastic component, and the movable plate and the flexible gas-sealed elastic component are fixedly connected; the flexible gas-sealed elastic component divides the sealed chamber into the upper sealed chamber and the lower sealed chamber that are not communicated with each other, and the flexible gas-sealed elastic component is fixedly connected to the sealed chamber housing; a gap is formed between the movable plate and the sealed chamber housing to allow the movable plate to move within the sealed chamber housing.

The flexible gas-sealed elastic component is annular, an inner periphery of the flexible gas-sealed elastic component is fixedly connected to a periphery of the movable plate, and the flexible gas-sealed elastic component is a silicone plate.

An upper fixing plate is provided above the flexible gas-sealed elastic component; the upper fixing plate and the movable plate clamp and fix the flexible gas-sealed elastic component; and a periphery of the upper fixing plate is located inside the periphery of the movable plate.

An upper end and a lower end of the corrugated pipe are respectively hermetically and fixedly connected to the gas-sealed elastic component and the sealed chamber housing through a corrugated pipe base.

A plate-type photovoltaic module laminator includes a rigid laminating plate, where the rigid laminating plate is located below a top of an upper box body and above a lamination worktable, and a laminating plate pressing drive device drives the laminating plate to move towards or away from the lamination worktable, where the aforementioned laminating plate pressing drive device is used, and the laminating plate is fixedly provided at the other end of the fixing shaft.

The laminating plate pressing drive device is located above the top of the upper box body the fixing shaft passes through a through hole provided in the top of the upper box body, and includes one end inside the upper box body and the other end outside the upper box body; the through hole provided in the upper box body for the fixing shaft to pass through is sealed by an upper box sealing and fixing structure located between a lower portion of the sealed chamber housing and the upper box body; and the lamination worktable is a heating plate, and a heating device is provided in the heating plate.

When the upper box body and the lamination worktable are closed, the upper box body works with the lamination worktable through a sealing assembly and a sealing ring that are located below the upper box body to form a sealed laminating working chamber.

A flexible gasket is provided on a lower surface of the laminating plate.

The photovoltaic module laminator is a multilayer photovoltaic module laminator, including at least two upper box bodies and lamination worktables, where a lamination worktable of an upper photovoltaic module laminator is supported by an upper box body of a lower photovoltaic module laminator.

The advantages and beneficial effects of the present invention are as follows:

In the adoption of the laminating plate pressing drive device and the plate-type photovoltaic module laminator in the structure of the present invention, the upper sealed chamber and the lower sealed chamber are provided, and a pressure difference generated by inflating the upper sealed chamber and vacuumizing the lower sealed chamber drives the laminating plate to move downwards and compress the photovoltaic module. Because the deflation and inflation pressures can be linearly adjusted, the pressure is more easily controlled. When a plurality of drive devices are configured to drive the identical laminating plate, each drive device can use the identical compressed air supply source and the identical vacuum extraction device to supply air and deflate air simultaneously, making the pressure applied by the laminating plate pressing drive device more balanced. In addition, according to the photovoltaic module laminator and its laminating plate pressing drive device in the structure of the present invention, the force for supporting the laminating plate is mainly from gas, which can achieve flexible pressure application while preventing the problem of easy damage to the gas-sealed elastic component. Compared to the pneumatic cylinder drive and the hydraulic cylinder drive, the laminating plate pressing drive device in the structure of the present invention does not have the guiding device on the fixing shaft, resulting in a certain amount of swaying during the downward movement of the laminating plate. Therefore, the laminating plate is in flexible contact with the module. When the plurality of drive devices are set, each drive device is controlled by the identical air source, resulting in consistent expansion and contraction of the gas-sealed elastic component. As a result, the time difference in contact with the photovoltaic module is small, the pressure application uniformity is good, and the stroke of each drive device is less different compared to mechanical types.

### BRIEF DESCRIPTION OF THE DRAWINGS

FIG. 1 is a structural schematic diagram of an embodiment of the bottom view of an upper box of a photovoltaic module laminator according to the present invention;

FIG. 2 is a front view of an overall structure of the photovoltaic module laminator according to the present invention;

FIG. 3 is a top view of the structure in FIG. 2;

FIG. 4 is a cross-sectional view of the structure in FIG. 3 taken along line A-A;

FIG. 5 is an enlarged view of portion C in FIG. 4;

FIG. 6 is an enlarged view of portion D in FIG. 4;

FIG. 7 is a structural schematic diagram of an embodiment of a multilayer photovoltaic module laminator; and

FIG. 8 is a cross-sectional view of the structure in FIG. 7 taken along line B-B.

### EXPLANATION OF REFERENCE NUMERALS IN THE DRAWINGS

1—photovoltaic module;
100—module transmission assembly;
200—laminating plate pressing drive device; 201—sealed chamber housing; 202—gas-sealed elastic component; 203—upper fixing plate; 204—gas channel; 205—corrugated sealing pipe; 206—upper sealed chamber; 207—lower sealed chamber; 208—corrugated pipe fixing base; 209—fixing shaft; and 210—movable plate;
300—upper box body; 301—upper box sealing and fixing structure; 302—sealing assembly; 303—laminating working chamber; and 305—sealing ring;
400—lower box; and 401—lamination worktable; and
500—pressure application component; 501—laminating plate; and 502—flexible gasket.

### DETAILED DESCRIPTION OF THE EMBODIMENTS

The present invention will be further described in detail below through specific embodiments. These embodiments are merely descriptive and not limitative, and should not be construed as limiting the scope of protection of the present invention.

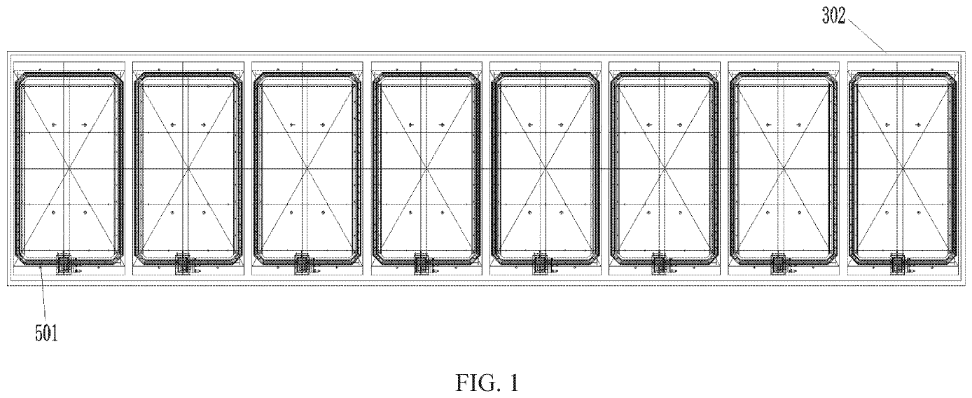

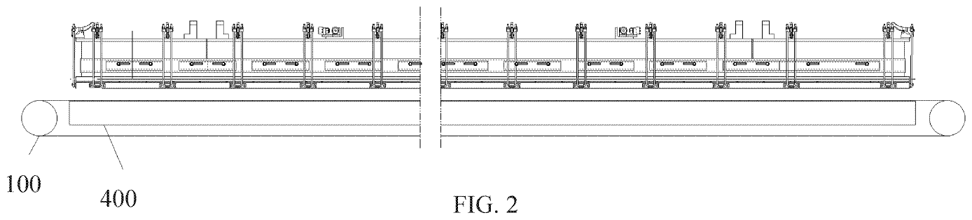

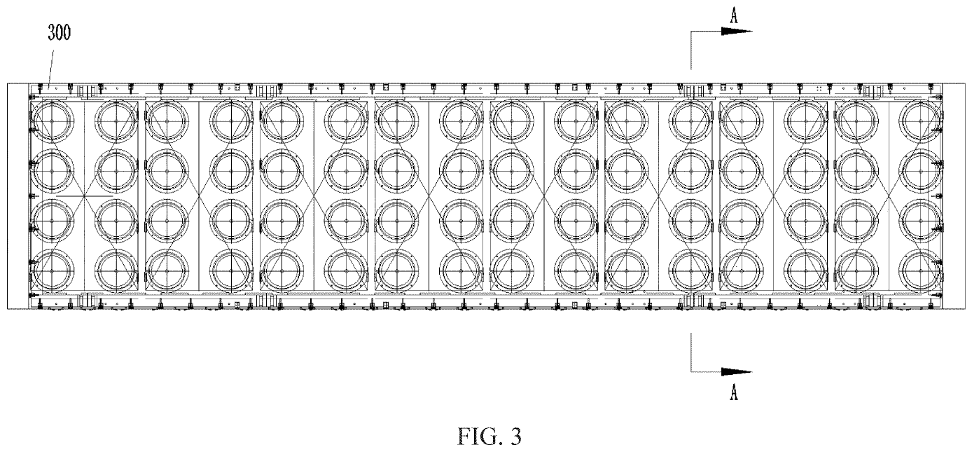

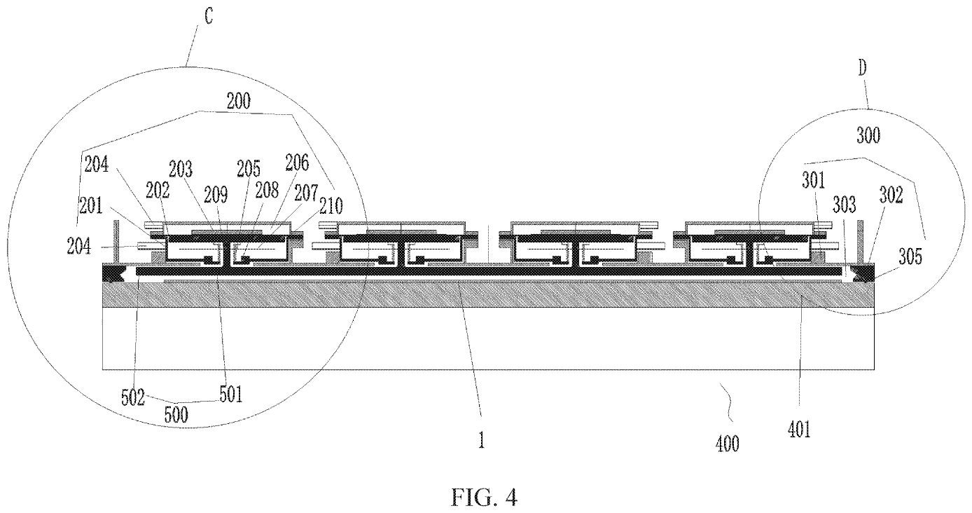

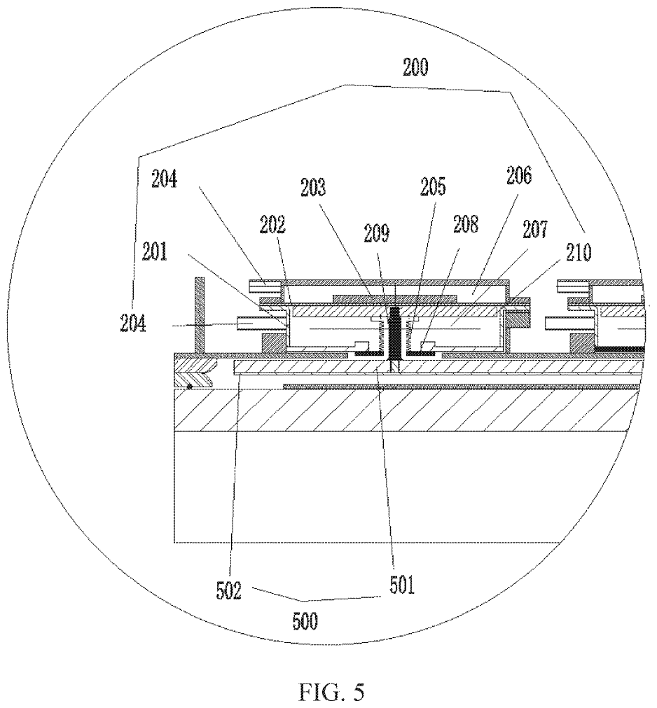

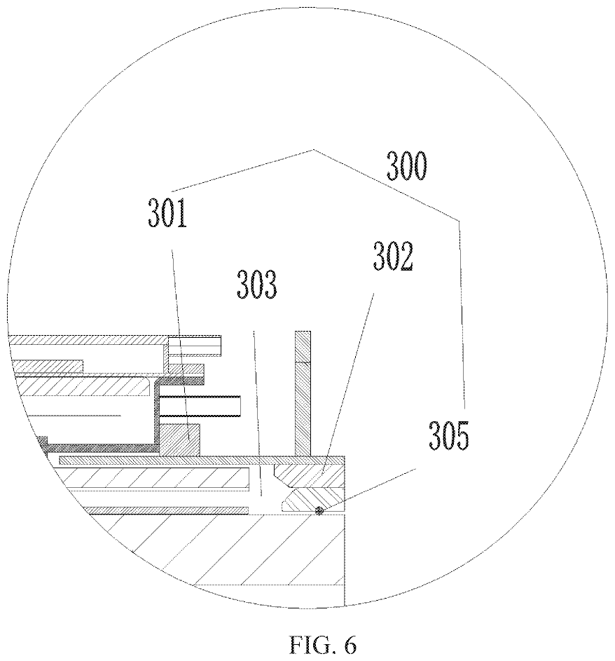

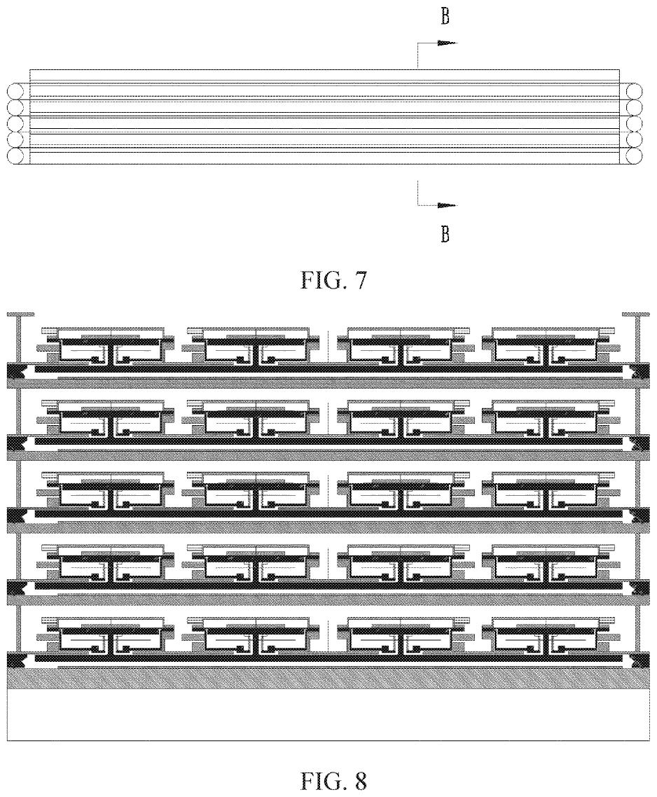

As shown in FIGS. 1-6, a laminating plate pressing drive device for a photovoltaic module laminator in the structure of the embodiment in the present invention includes the sealed chamber housing 201. The gas-sealed elastic component 202 is provided within the sealed chamber housing. The periphery of the gas-sealed elastic component 202 is fixedly connected to the sealed chamber housing, and divides the sealed chamber housing into the upper sealed chamber 206 and the lower sealed chamber 207 that are sealed and not communicated with each other. Both the upper sealed chamber and the lower sealed chamber are respectively provided with gas channels 204 that are communicated with a vacuum extraction device and an inflation device. The sealing corrugated pipe is provided within the lower sealed chamber. The upper end and the lower end of the sealing corrugated pipe are respectively hermetically and fixedly connected to the lower surface of the gas-sealed elastic component 202 and the bottom of the sealed chamber housing through a corrugated pipe base, so that the lower sealed chamber is not communicated with the inner cavity of the corrugated pipe. The fixing shaft 209 is fixedly provided on the lower surface of the gas-sealed elastic component 202. The fixing shaft 209 is located inside the inner cavity of the corrugated pipe, and the lower end of the fixing shaft is configured to be fixedly connected to the laminating plate 501. In the adoption of the laminating plate pressing drive device of the structure of the present invention, the gas-sealed elastic component 202 is employed to isolate the upper sealed chamber and the lower sealed chamber. By inflating and deflating the upper sealed chamber and the lower sealed chamber, the pressure difference is generated on both sides of the gas-sealed elastic component to drive the gas-sealed elastic component to move upwards or downwards, thereby driving the laminating plate to move upwards or downwards. As a result, the photovoltaic modules are compressed, or the photovoltaic modules are separated. It is convenient and accurate to adjust a gas pressure, and the pressure increase is linear, resulting in gentle pressure application and easy control, which is beneficial for controlling the pressure on the photovoltaic module. The plurality of laminating plate pressing drive devices can be connected to the identical compressed air source; therefore, the pressures applied by the plurality of laminating plate pressing drive devices are well-coordinated and easily controlled. In the structure of the present invention, the gas-sealed elastic component can be flexible or semi-flexible. When the flexible gas-sealed elastic component is used, the planar structure can be made of one or more of the following materials: silicone plate, high gas-sealed bio-based aromatic polyester elastomer, thermoplastic elastomer with the gas-sealed layer, and high gas-sealed bio-based thiophene polyester elastomer. When the semi-flexible gas-sealed elastic component is used, the structure combining the flexible gas-sealed elastic component and the rigid component can be adopted. For example, the periphery of the flexible gas-sealed elastic component is fixedly connected to the inner circumference of the sealed chamber housing, and divides the sealed chamber into the upper sealed chamber and the lower sealed chamber. The movable plate 210 is fixedly provided on the lower surface of the flexible gas-sealed elastic component, and the upper end of the fixing shaft is fixedly connected to the lower surface of the movable plate 210. A gap is formed between the periphery of the movable plate and the inner circumference of the sealed chamber housing to allow the movable plate to move. In this way, the flexible gas-sealed elastic component is supported by the movable plate. When the upper sealed chamber is inflated, the flexible gas-sealed elastic component deforms and elongates but does not form the bladder-like expansion, which is beneficial for the laminating plate to stably move upwards or downwards. To increase the firmness of the connection between the flexible gas-sealed elastic component and the movable plate, the upper fixing plate 203 is provided. The flexible gas-sealed elastic component is located between the upper fixing plate and the movable plate and is clamped and fixed by the two, which can prevent the flexible gas-sealed elastic component from separating from the movable plate under the action of pressure difference. For example, the upper fixing plate and the movable plate can be fastened by bolts. Preferably, the perimeter of the upper fixing plate is shorter than the perimeter of the movable plate, so that the flexible gas-sealed elastic component has a portion that is located above the movable plate and not pressed down by the upper fixing plate. This allows the flexible gas-sealed elastic component to be supported over the larger area while having sufficient elastic deformation space for moving upwards or downwards. Alternatively, the flexible gas-sealed component can be annular, surrounding the perimeter of the movable plate. The outer perimeter of the flexible gas-sealed component is fixedly connected to the sealed chamber housing, and the inner perimeter of the flexible gas-sealed component is fixedly connected to the outer perimeter of the movable plate. The upper fixing plate can be annular, is pressed against and fixed above the inner perimeter of the flexible gas-sealed component by bolts or other fastening devices, and works with the movable plate to clamp and fix the flexible gas-sealed component. Similarly, the outer perimeter of the upper fixing plate can be located inside the outer perimeter of the movable plate. Alternatively, the fixed portion of the flexible gas-sealed component has a certain distance from the outer perimeter of the movable plate, allowing the flexible gas-sealed component to have an extendable annular portion.

In use, the laminating plate pressing drive device can be provided either on the outer side of the top of the laminating working chamber or on the inner side of the laminating working chamber, depending on the specific working conditions. Now, taking the example of the laminating plate pressing drive device being provided on the outer side of the upper box body, the technical content of the present invention will be described in further detail.

The plate-type photovoltaic module laminator in the structure of the embodiment in the present invention includes the upper box body, the lamination worktable, the laminating plate 501, and the laminating plate pressing drive device 200 with the aforementioned structure. The laminating plate is the rigid, high-temperature resistant plate structure. The lamination worktable is supported by the lower box body. The laminating plate is horizontally positioned within the upper box body, and the lamination worktable is located below the laminating plate. The lamination worktable serves as the device supporting the photovoltaic module 1, and works with the laminating plate to compress the photovoltaic module. Driven by the upper box lifting drive device (not shown in the figure), the upper box body can rise or lower, thereby adjusting the distance between the laminating plate and the worktable, allowing the laminating plate pressing drive device to perform lamination within a small stroke. This process is also referred to as the opening and closing process of the photovoltaic module laminator. The laminating plate pressing drive device is entirely located outside the top of the upper box and is supported and fixed by the top of the upper box. The top of the upper box is provided with a through hole for a fixing shaft to pass through. The fixing and sealing structure 301 is further provided outside the top of the upper box or the laminating working chamber and configured to fix and accommodate the sealed chamber housing. The fixing and sealing structure is hermetically and fixedly connected to the sealed chamber housing to form the structure in which the laminating working chamber is communicated with the inner cavity of the corrugated pipe and the inner cavity of the fixing and sealing structure 301. This prevents air leakage from the upper box at the through hole through which the fixing shaft passes, ensuring that the upper box is firmly and reliably sealed. The laminating plate pressing drive device 200 is configured to drive the laminating plate to move towards or away from the lamination worktable, so that the laminating plate and the lamination worktable together apply a pressure to the photovoltaic module or are in contact with the photovoltaic module without applying the pressure.

The plate-type photovoltaic module laminator in the structure of the present invention can be used for vacuum lamination as well as non-vacuum lamination. It can be used for vacuum or non-vacuum lamination curing, and can also be used for non-vacuum cooling and pressurization. When operating under vacuum, the laminating working chamber formed by the upper box and the lamination worktable is required as a sealed chamber capable of being vacuumized and inflated. When the laminating working chamber is the sealed chamber, the sealing assembly 302 is provided at the lower end of the upper box body, and sealing is achieved through the sealed chamber II provided below the sealing assembly.

Each laminating working chamber can be provided with one laminating plate, and each laminating plate is at least correspondingly equipped with one laminating plate pressing drive device. Typically, 4-8 laminating plate pressing drive devices are provided to ensure stable operation of the laminating plates. Such design can reduce a driving force of each laminating plate pressing drive device and also reduce the length, width and thickness of the flexible gas-sealed elastic component, thus increasing the service life of the flexible gas-sealed elastic component. Furthermore, when any flexible gas-sealed elastic component is damaged, it can be replaced individually, thereby reducing maintenance difficulty and saving production costs.

Taking vacuum lamination as an example, the working process of the laminator and its laminating plate pressing drive device of the present invention is illustrated as follows: In the initial state, the upper box body is in an open position, the upper sealed chamber is in a vacuum state, and the lower sealed chamber is in an inflated state. An optical module enters a designated position of the lamination worktable through the module transmission assembly 100. When laminating, the upper box body is driven to move downwards, and its sealing ring encounters and closes with the lamination worktable to form the sealed laminating working chamber. After the cover is closed, the upper space and the lower space of the laminating plate are communicated with each other under the identical air pressure. The laminating working chamber is vacuumized to a certain vacuum degree, the upper sealed chamber begins to be inflated, and the lower sealed chamber begins to be vacuumized, causing the flexible gas-sealed elastic component to deform downwards. The movable plate and the fixing shaft move downwards together with the laminating plate, so that the laminating plate comes into contact with the component to perform lamination. At the same time, as the vacuum chamber pressure increases, the lamination pressure will increase until a process pressure is reached. After lamination is completed, the laminating working chamber is inflated, the lower sealed chamber is inflated, and the upper sealed chamber is vacuumized. The pressure above the flexible gas-sealed elastic component decreases, while the pressure below the flexible gas-sealed elastic component increases. When the pressure below the flexible gas-sealed elastic component exceeds the pressure above the flexible gas-sealed elastic component, the deformation of the flexible gas-sealed elastic component decreases until it returns to the initial state. Then, deflation of the upper sealed chamber and inflation of the lower sealed chamber are stopped, the cover is opened, and the module is transferred out of the laminating working chamber. The photovoltaic module laminator in the structure of the present invention can perform continuous pressurization and depressurization on the laminating plate because the driving force of the laminating plate is determined by the inflation pressure in the upper sealed chamber and the vacuum degree in the lower sealed chamber. Furthermore, one laminating plate can be provided with two or more laminating plate pressing drive devices, thus providing a high lamination pressure. The increase in the lamination pressure is continuous, resulting in better module lamination uniformity, less residual air, and improved performance in addressing air bubbles in the module caused by residual air and uneven lamination of the module. This structure is an independent lamination structure, and one or more modules can be laminated using the independent laminating plate. Throughout the lamination process, since the gas-sealed elastic component is supported by gas, it is only subjected to its own tension and thus uneasily damaged.

According to the photovoltaic module laminator of the present invention, since no mechanical device such as the pneumatic cylinder, the hydraulic cylinder or the like is provided, the height of the laminating plate pressing drive device can be significantly reduced, which is advantageous for use in a multilayer photovoltaic module laminator.

The present invention provides the multilayer photovoltaic module laminator, where each layer of the photovoltaic module laminator adopts the structure of the aforementioned single-layer photovoltaic module laminator. Two adjacent single-layer photovoltaic module laminators (the single-layer photovoltaic module laminator is hereinafter referred to as a photovoltaic module laminator) are arranged vertically. The support frame is provided on the top of the upper box body. The lower box of the upper and lower photovoltaic module laminators is supported by the support frame of the upper photovoltaic module laminator, and the upper box of each layer of the photovoltaic module laminator is supported by the upper box body drive device.

The flexible gasket is preferably provided on the lower surface of the laminating plate. During lamination, the flexible gasket is in contact with the photovoltaic module, thus reducing the impact between the rigid laminating plate and the photovoltaic module, and reducing or preventing damage to the photovoltaic module.

A flexible high-temperature resistant elastic sealing component can be a sheet-like component made of one or more of the following materials: elastic gas-sealed fabric, high-airtightness bio-based aromatic polyester elastomer material, thermoplastic elastomer with the gas-sealed layer, and high-airtightness bio-based thiophene polyester elastomer material.

What is claimed is:

1. A laminating plate pressing drive device for a photovoltaic module laminator, comprising a sealed chamber housing; wherein a gas-sealed elastic component is provided within the sealed chamber housing; an outer periphery of the gas-sealed elastic component is fixedly connected to a side of the sealed chamber housing, and divides a sealed chamber into an upper sealed chamber and a lower sealed chamber, wherein the upper sealed chamber and the lower sealed chamber are not communicated with each other; a corrugated pipe is provided within the lower sealed chamber; a first end of the corrugated pipe is hermetically and fixedly connected to the gas-sealed elastic component, and a second end of the corrugated pipe is fixedly connected to a lower end of the sealed chamber housing; a fixing shaft is located inside the corrugated pipe, wherein a first end of the fixing shaft is fixedly connected to the gas-sealed elastic component, and a second end of the fixing shaft is configured to be fixedly connected to a laminating plate; and both the upper sealed chamber and the lower sealed chamber are provided with gas channels, wherein the gas channels are communicated with a vacuum device and an inflation device.

2. The laminating plate pressing drive device for the photovoltaic module laminator according to claim 1, wherein the gas-sealed elastic component comprises a flexible gas-sealed elastic component and a movable plate, the movable plate is located below the flexible gas-sealed elastic component, and the movable plate and the flexible gas-sealed elastic component are fixedly connected; the flexible gas-sealed elastic component divides the sealed chamber into the upper sealed chamber and the lower sealed chamber, wherein the upper sealed chamber and the lower sealed chamber are not communicated with each other, and the flexible gas-sealed elastic component is fixedly connected to the sealed chamber housing; and a gap is formed between the movable plate and the sealed chamber housing to allow the movable plate to move within the sealed chamber housing.

3. The laminating plate pressing drive device for the photovoltaic module laminator according to claim 2, wherein the flexible gas-sealed elastic component is annular, an inner periphery of the flexible gas-sealed elastic component is fixedly connected to a periphery of the movable plate, and the flexible gas-sealed elastic component is a silicone plate.

4. The laminating plate pressing drive device for the photovoltaic module laminator according to claim 2, wherein an upper fixing plate is provided above the flexible gas-sealed elastic component; the upper fixing plate and the movable plate clamp and fix the flexible gas-sealed elastic component; and a periphery of the upper fixing plate is located inside a periphery of the movable plate.

5. The laminating plate pressing drive device for the photovoltaic module laminator according to claim 1, wherein an upper end of the corrugated pipe and a lower end of the corrugated pipe are respectively hermetically and fixedly connected to the gas-sealed elastic component and the sealed chamber housing through a corrugated pipe base.

6. A plate-type photovoltaic module laminator, comprising a rigid laminating plate, wherein the rigid laminating plate is located below a top of an upper box body and above a lamination worktable, and the laminating plate pressing drive device drives the laminating plate to move towards or away from the lamination worktable, wherein the laminating plate pressing drive device according to claim 1 is used, and the laminating plate is fixedly provided at the second end of the fixing shaft.

7. The plate-type photovoltaic module laminator according to claim 6, wherein the laminating plate pressing drive device is located above the top of the upper box body; the fixing shaft passes through a through hole provided in the top of the upper box body, and the fixing shaft comprises a first end inside the upper box body and a second end outside the upper box body;
the through hole provided in the upper box body for the fixing shaft to pass through is sealed by an upper box sealing and fixing structure located between a lower portion of the sealed chamber housing and the upper box body; and the lamination worktable is a heating plate, and a heating device is provided in the heating plate.

8. The plate-type photovoltaic module laminator according to claim 6, wherein when the upper box body and the lamination worktable are closed, the upper box body works with the lamination worktable through a sealing assembly and a sealing ring to form a sealed laminating working chamber, wherein the sealing assembly and the sealing ring are located below the upper box body.

9. The plate-type photovoltaic module laminator according to claim 6, wherein a flexible gasket is provided on a lower surface of the laminating plate.

10. The plate-type photovoltaic module laminator according to claim 6, wherein the plate-type photovoltaic module laminator is a multilayer photovoltaic module laminator, comprising at least two upper box bodies and at least two lamination worktables, wherein a lamination worktable of an upper photovoltaic module laminator is supported by an upper box body of a lower photovoltaic module laminator.

11. The laminating plate pressing drive device for the photovoltaic module laminator according to claim 3, wherein an upper fixing plate is provided above the flexible gas-sealed elastic component; the upper fixing plate and the movable plate clamp and fix the flexible gas-sealed elastic component; and a periphery of the upper fixing plate is located inside the periphery of the movable plate.

12. The plate-type photovoltaic module laminator according to claim 6, wherein in the laminating plate pressing drive device, the gas-sealed elastic component comprises a flexible gas-sealed elastic component and a movable plate, the movable plate is located below the flexible gas-sealed elastic component, and the movable plate and the flexible gas-sealed elastic component are fixedly connected; the flexible gas-sealed elastic component divides the sealed chamber into the upper sealed chamber and the lower sealed chamber, wherein the upper sealed chamber and the lower sealed chamber are not communicated with each other, and the flexible gas-sealed elastic component is fixedly connected to the sealed chamber housing; and a gap is formed between the movable plate and the sealed chamber housing to allow the movable plate to move within the sealed chamber housing.

13. The plate-type photovoltaic module laminator according to claim 12, wherein in the laminating plate pressing drive device, the flexible gas-sealed elastic component is annular, an inner periphery of the flexible gas-sealed elastic component is fixedly connected to a periphery of the movable plate, and the flexible gas-sealed elastic component is a silicone plate.

14. The plate-type photovoltaic module laminator according to claim 12, wherein in the laminating plate pressing drive device, an upper fixing plate is provided above the flexible gas-sealed elastic component; the upper fixing plate and the movable plate clamp and fix the flexible gas-sealed elastic component; and a periphery of the upper fixing plate is located inside a periphery of the movable plate.

15. The plate-type photovoltaic module laminator according to claim 6, wherein in the laminating plate pressing drive device, an upper end of the corrugated pipe and a lower end of the corrugated pipe are respectively hermetically and fixedly connected to the gas-sealed elastic component and the sealed chamber housing through a corrugated pipe base.
